(19) United States
(12) Patent Application Publication
(10) Pub. No.: US 2010/0012153 A1
(43) Pub. Date: Jan. 21, 2010

(54) METHOD OF CLEANING FILM FORMING APPARATUS AND FILM FORMING APPARATUS

(76) Inventors: Takamitsu Shigemoto, Chiba-Pref. (JP); Jun Sonobe, Ibaraki-Pref. (JP)

Correspondence Address: AIR LIQUIDE;Intellectual Property, 2700 POST OAK BOULEVARD, SUITE 1800, HOUSTON, TX, 77056, US

(21) Appl. No.: 12/374,364

(22) PCT Filed: Jul. 26, 2007
(86) PCT No.: PCT/IB07/02145

§ 371 Date: Oct. 1, 2009

Related U.S. Application Data
(60) Provisional application No. 60/870,535, filed on Dec. 18, 2006.

(30) Foreign Application Priority Data
Jul. 27, 2006 (JP) 2006-204761

(51) Int. Cl. B08B 9/00; C23C 16/00

(52) U.S. Cl. 134/22.1; 118/724

(57) ABSTRACT

To provide a method of cleaning a film forming apparatus capable of uniformly removing a deposit containing tantalum nitride, titanium nitride, tantalum, or titanium adhering to a wall of a processing chamber of the film forming apparatus at a high etching rate without use of plasma. A method of cleaning a film forming apparatus for removing a deposit containing tantalum nitride, titanium nitride, tantalum, or titanium deposited on a processing chamber of the film forming apparatus after it is used for forming a thin film made of tantalum nitride, titanium nitride, tantalum, or titanium, the cleaning method comprising: a step of supplying process gas containing fluorine gas into the processing chamber of the film forming apparatus; and a step of heating the processing chamber.

### TECHNICAL FIELD

The present invention relates to a method of cleaning a film forming apparatus, and a film forming apparatus with a cleaning system.

### BACKGROUND ART

In the process of manufacturing a semiconductor device, a tantalum nitride (TaN) or a titanium nitride (TiN) film which functions as a barrier film on a semiconductor wafer is formed by using a film forming apparatus equipped with a processing chamber for thermochemical vapor deposition (thermo CVD) or atomic layer deposition (ALD). Upon formation of the TaN or TiN thin film, a reaction product in the processing chamber is deposited not only on the semiconductor wafer but also on the wall of the processing chamber and a supporting member (for example, susceptor) of the semiconductor wafer. The deposited reaction product containing TaN or TiN is peeled from the inner wall or the like of the processing chamber, thereby resulting in generation of particles. The particles adhere to the semiconductor wafer at the time of next formation of the TaN or TiN film on the semiconductor wafer, thereby deteriorating the quality of the TaN or TiN film. Thus, cleaning of the film forming apparatus is needed.

For example, wet cleaning which removes a deposit containing TaN or TiN adhering to the wall of the processing chamber with an etchant like an acid solution has been conventionally well known. However, this method needs complicated long cleaning treatment of cleaning the processing chamber with the acid solution, washing with water, and removing water after the film forming apparatus is stopped, that is, an interruption time of the film forming apparatus is prolonged, thereby resulting in reduction of productivity.

On the other hand, Patent Documents 1, 2, and 3 have disclosed methods of etching tantalum nitride (TaN) in manufacturing of a semiconductor device. The Patent Document 1 describes that TaₓN_{y} is etched selectively by two steps, that is, two steps of a first step of plasma processing of N₂ and NH₃ as active gas and a second step of plasma processing of O₂ and C₂F₄ as active species. The Patent Document 2 describes that TaN can be etched at a high etching selection ratio with respect to an insulating film by plasma processing using gas containing SiCl₄, NF₃, and O₂. The Patent Document 3 describes removing selectively TaN with respect to a Cu layer by oxidation plasma chemical processing with O₂/O₂F₄.

However, if plasma etching processing of tantalum nitride (TaN) or titanium nitride (TiN) is applied to cleaning of a deposit containing tantalum nitride or titanium nitride in the processing chamber, a thermo CVD film forming apparatus needs, for example, an expensive plasma generating equipment, thereby inducing boosting of running cost and equipment cost.

Patent Document 1, US-A-2004/0058528

Patent Document 2, US-A-2005/0095867

Patent Document 3, US-A-2005/0250337

### PROBLEM TO BE SOLVED

The present invention provides a method of cleaning a film forming apparatus capable of uniformly removing a deposit containing tantalum nitride, titanium nitride, tantalum, or titanium adhering to a wall of a processing chamber of a film forming apparatus at a high etching rate without use of plasma, and the same film forming apparatus.

### MEANS FOR SOLVING THE PROBLEM

According to a first aspect of the present invention, there is provided a method of cleaning a film forming apparatus for removing a deposit containing tantalum nitride, titanium nitride, tantalum, or titanium deposited on a processing chamber of the film forming apparatus after it is used for forming a thin film made of tantalum nitride, titanium nitride, tantalum, or titanium, the cleaning method comprising:

a step of supplying process gas containing fluorine gas into the processing chamber of the film forming apparatus; and

a step of heating the processing chamber.

According to a second aspect of the present invention, there is provided a film forming apparatus which forms a thin film made of tantalum nitride, titanium nitride, tantalum, or titanium on a wafer within a processing chamber, comprising:

raw material supply means for supplying raw material gas for forming a thin film made of tantalum nitride, titanium nitride, tantalum, or titanium in the processing chamber;

process gas supply means for supplying process gas containing fluorine gas into the processing chamber; and

heating means for heating the processing chamber.

### ADVANTAGE OF THE INVENTION

According to the present invention, the deposit containing tantalum nitride, titanium nitride, tantalum, or titanium adhering to the wall of the processing chamber of the film forming apparatus can be removed uniformly at a high etching rate. When a thin film made of tantalum nitride, titanium nitride, tantalum, or titanium is formed on a next wafer, a high quality thin film made of tantalum nitride, titanium nitride, tantalum, or titanium without deterioration originating from particles can be formed.

### BEST MODE FOR CARRYING OUT THE INVENTION

Hereinafter, embodiments of the present invention will be described.

An embodiment is a cleaning method in which process gas containing fluorine gas (F₂ gas) is supplied to a processing chamber of a film forming apparatus after a thin film made of tantalum nitride, titanium nitride, tantalum, or titanium is formed, and a deposit containing tantalum nitride, titanium nitride, tantalum, or titanium deposited on a wall and the like of the processing chamber is removed by heating the processing chamber.

Another embodiment is a cleaning method in which process gas containing fluorine gas with nitric oxide (NO) added is introduced into a processing chamber of a film forming apparatus after a thin film made of tantalum nitride, titanium nitride, tantalum, or titanium is formed, and a deposit containing tantalum nitride, titanium nitride, tantalum, or titanium is deposited on a wall and the like of the processing chamber is removed by heating the processing chamber.

The film forming apparatus includes a processing chamber for, for example, thermo CVD or ALD. As the film forming apparatus, sheet feed type or batch type is available. In case of the sheet feed type, a susceptor in which a semiconductor wafer conveyed into the processing chamber is placed is disposed. In case of the batch type, a boat accommodating a plurality of semiconductor wafers in the processing chamber is disposed.

Hereinafter, the sheet feed type thermo CVD film forming apparatus for forming a tantalum nitride or titanium nitride thin film shown in FIG. 1 will be described in detail.

The processing chamber 1 is formed of, for example, metal like aluminum or alloy such as aluminum alloy, monel and inconel, and provided with gate valves for loading and unloading which carries in and carries out a semiconductor wafer, as indicated on the front and rear sides with respect to this drawing. In case of the sheet feed type, a susceptor 2 on which a semiconductor wafer is supported is disposed in the processing chamber 1 and supported by a supporting shaft 3. A heater 4 is incorporated in the susceptor 2. An exhaust pipe 5 is connected to a side wall of a lower portion of the processing chamber 1, and the other end thereof communicates with exhaust equipment (not shown) such as a mechanical booster pump or rotary pump. In the meantime, it is permissible to arrange other heater than the heater 4 incorporated in the susceptor 2 on the outer periphery of the processing chamber 1.

Thin film forming raw material gas supply means 11 includes a first supply pipe 12 connected to a gas supply source of a tantalum, or titanium type precursor, a second supply pipe 13 connected to an ammonia gas supply source, and a third supply pipe 14 connected to an inert gas supply source. These first to third supply pipes 12, 13 and 14 are connected to the processing chamber 1 through a main supply pipe 15. Mass flow controllers MFC1 to MFC3 are provided on the first to third supply pipes 12, 13 and 14, respectively. An on-off valve V1 is provided on the main supply pipe 15.

Examples of tantalum and titanium type precursors include, but are not limited to, Pentaethoxy Tantalum (Ta(OEt)5), Tetraethoxydimethylaminoethoxide Tantalum (Ta(OEt)4(OEtNMe)2), (tert-butylimino)tris(diethylamino) Tantalum ((Et2N)3Ta=NtBu), Tertiary(amylimino) tris(dimethylamino) Tantalum ((Me2N)3Ta=NAm), Pentakis(dimethylamino) Tantalum (Ta[NMe2]5), Tantalum Pentachloride (TaCl5), Tantalum Pentachloride-diethylsulfur adduct (TaCl5-SEt2), Tantalum pentafluoride (TaF5), Tetrachloro Titanium (TiCl₄), Tetrakisdiethylamino Titanium (Ti(NEt₂)₄), Tetrakisdimethylamino Titanium (Ti(NMe₂)₄), Titanium (IV) isopropoxide (Ti(OᵢPr)₄), Tetrakis(diethylmethylamino) titanium (Ti[NEtMe]₄), Titanium Di(i-propoxy)bis(diisobutyrylmethanate) (Ti(OiPr)₂(dibm)₂), Titanium Di(i-propoxy)bis(diisobutyrylmethanate) (Ti(OiPr)₂(dpm)₂), Pentaethoxy Tantalum (Ta(OEt)5), Tetraethoxydimethylaminoethoxide Tantalum (Ta(OEt)4(OEtNMe)2), (tert-butylimino)tris(diethylamino) Tantalum ((Et2N)3Ta=NtBu), Tertiary(amylimino) tris(dimethylamino) Tantalum ((Me2N)3Ta=NAm), Pentakis(dimethylamino) Tantalum (Ta[NMe2]5), Tantalum Pentachloride (TaCl5), Tantalum Pentachloride-diethylsulfur adduct (TaCl5-SEt2), Tantalum pentafluoride (TaF5).

Process gas supply means 21 includes a fourth supply pipe 22 connected to a fluorine gas (F₂) supply source, a fifth supply pipe 23 connected to a nitric oxide (NO) supply source, and a sixth supply pipe 24 connected to an inert gas supply source. These fourth to sixth supply pipes 22, 23 and 24 are connected to the processing chamber 1 through a main supply pipe 25. Mass flow controllers MFC4 to MFC6 are provided on the fourth to sixth supply pipes 22, 23 and 24. A mixer 26 and an on-off valve V2 are provided on the main supply pipe 25 in succession from the side of the fourth to sixth supply pipes 22, 23 and 24.

Formation of a tantalum nitride or titanium nitride thin film on the semiconductor wafer using such a sheet-feed type thermo CVD film forming apparatus, and cleaning of the film will be described below.

A semiconductor wafer 30 is carried onto the susceptor 2 within the processing chamber 1 from a gate valve on the load side (not shown). Gas in the processing chamber 1 is discharged through the exhaust pipe 5 by actuating exhaust equipment connected to the exhaust pipe 5. After the processing chamber 1 reaches a desired pressure, the on-off valve V1 of the raw material gas supply means 11 is opened while continuing to discharge exhaust gas so as to supply the precursor gas, ammonia gas, and inert gas (for example, argon gas) from the precursor gas supply source, ammonia gas supply source and inert gas supply source into the processing chamber 1 through the first to third supply pipes 12, 13, and 14 and the main supply pipe 15. At this time, the flow quantities of precursor gas, ammonia gas and argon gas flowing through the first to third supply pipes 12, 13, and 14 are adjusted by the mass flow controllers MFC1 to MFC3 provided on the supply pipes 12, 13, and 14. After pressure in the processing chamber 1 is stabilized, a tantalum nitride (TaN) or titanium nitride (TiN) film is formed on the wafer 30 by heating the semiconductor wafer 30 with the heater 4 of the susceptor 2 so as to react the precursor in raw material gas with ammonia. After the TaN or TiN thin film is formed, the wafer 30 is carried out of the processing chamber 1 (for example, to a processing chamber on a next process) through a gate valve on the unload side.

If deposit containing tantalum nitride or titanium nitride adheres to the inner wall face of the processing chamber 1 (unreactive substance of precursor is mixed in some cases) after formation of the tantalum nitride or titanium nitride thin film on the semiconductor wafer is performed at least once, the following cleaning is executed.

After the semiconductor wafer having the tantalum nitride or titanium nitride thin film formed thereon is carried out of the processing chamber 1, the on-off valve of the raw material gas supply means 11 is closed, and gas in the processing chamber 1 is discharged through the exhaust pipe 5 by actuating the exhaust equipment connected to the exhaust pipe 5 while continuing to heat. At this time, it is permissible to replace the atmosphere in the processing chamber 1 with nitrogen atmosphere having a desired pressure (reduced pressure) by opening the on-off valve V2 of the process gas supply means 21 and supplying only nitrogen (N₂) gas from the inert gas supply source into the processing chamber 1 through the sixth supply pipe 24 and the main supply pipe 25.

After the processing chamber reaches a desired pressure, the on-off valve V2 of the process gas supply means 21 is opened while continuing to heat with the heater 4 of the susceptor 2 and discharge exhaust gas so as to supply fluorine gas and inert gas (for example, nitrogen gas) from the fluorine gas supply source and the inert gas supply source to the main supply pipe 25 through the fourth and sixth supply pipes 22, 24. The flow quantities of fluorine gas and nitrogen gas flowing through the fourth and sixth supply pipes 22 and 24 are adjusted by the mass flow controllers MFC4 and MFC6 provided on the supply pipes 22, 24. After the flow quantity is adjusted, the fluorine gas and nitrogen gas are mixed by the mixer 26 provided on the main supply pipe 25, and the mixed gas is supplied into the processing chamber 1 through the main supply pipe 25. A deposit containing tantalum nitride or titanium nitride deposited on the inner wall (and peripheral face of the susceptor 2) of the processing chamber 1 is reacted and removed for cleaning by strong etching action and thermal energy of fluorine gas controlled to a reduced pressure when the mixed gas is supplied.

According to another embodiment, after the processing chamber 1 reaches a desired pressure, the on-off valve V2 of the process gas supply means 21 is opened while continuing to heat with the heater 4 of the susceptor 2 and discharge exhaust gas so as to supply F₂ gas, NO gas and inert gas (for example, N₂ gas) to the main supply pipe 25 from the fluorine gas supply source, the nitric oxide supply source and inert gas supply source through the fourth to sixth supply pipes 22, 23 and 24. At this time, the flow quantities of F₂ gas, NO gas and N₂ gas flowing through the fourth, fifth and sixth supply pipes 22, 23 and 24 are adjusted by the mass flow controllers MFC4, MFC5 and MFC6 provided on the supply pipes 22, 23 and 24. After the flow quantity is adjusted, F₂ gas, NO gas and N₂ gas are mixed by the mixer 26 provided on the main supply pipe 25, and the mixed gas is supplied into the processing chamber 11 through the main supply pipe 25. A deposit containing tantalum nitride or titanium nitride deposited on the inner wall (and peripheral face of the susceptor 2) of the processing chamber 1 is reacted and removed for cleaning by strong etching action and thermal energy of F₂ gas and NO gas controlled to a reduced pressure when the mixed gas is supplied.

As formation of a tantalum nitride or titanium nitride thin film using the above film forming apparatus has been described above, a tantalum, or titanium thin film can be formed on the semiconductor wafer by supplying precursor gas and argon to the processing chamber. In this case, a deposit containing tantalum or titanium adheres to the wall of the processing chamber (unreactive substance of precursor is mixed in some cases).

The process gas is preferred to be mixed gas of fluorine gas and inert gas as described above. However, it is permissible to use process gas composed of only fluorine gas. Particularly, the process gas is preferred to be mixed gas having composition of 5 to 80% by volume of fluorine gas while the remainder is composed of inert gas. If the quantity of fluorine gas in the process gas is set to less than 5% by volume, it may be difficult to effectively remove tantalum nitride, titanium nitride, or deposits containing tantalum, or titanium deposited on the inner wall of the processing chamber by means of etching. The preferred quantity of fluorine gas is 10 to 50% by volume. As the inert gas, for example, rare gas such as nitrogen gas, argon gas, and helium gas may be used.

The process gas with nitric oxide added is preferred to have a composition comprised of 5 to 80% by volume of fluorine gas and 1 to 20% by volume of nitric oxide gas while the remainder is composed of inert gas. By using process gas containing the fluorine gas and nitric oxide gas having such a composition, a deposit containing tantalum nitride or titanium nitride deposited on the inner wall of the processing chamber can be removed more effectively by etching. The quantities of fluorine gas and nitric oxide gas in a more preferred process gas are 10 to 50% by volume and 1 to 10% by volume, respectively. Particularly, the fluorine gas and nitric oxide gas in the process gas are preferred to be so set that a ratio R of the fluorine (F₂)/nitric oxide (NO) is 1≦R≦4 in the above-described range of the quantity.

Preferably, the pressure in the processing chamber when a deposit is removed by supplying process gas into the processing chamber is 1 to 700 Torr, and more preferably, 1 to 100 Torr.

Heating of the processing chamber is preferred to be carried out at temperatures of 100° C. to 500° C. Heating at such temperatures enables a deposit containing tantalum nitride, titanium nitride, tantalum, or titanium adhering to the wall of the processing chamber to be cleaned at a sufficient etching rate. Particularly, if the heating temperature is less than 100° C., a deposit containing tantalum nitride, titanium nitride, tantalum, or titanium deposited on the inner wall of the processing chamber can be removed sufficiently. A preferred heating temperature is 250° C. to 500° C. In the meantime, heating may be carried out by using another heater disposed on the outer periphery of the processing chamber in addition to the heater of the susceptor shown in FIG. 1.

According to an embodiment, by supplying process gas (for example, mixed gas of fluorine gas and inert gas) into the processing chamber of the film forming apparatus and heating the processing chamber, a deposit containing tantalum nitride, titanium nitride, tantalum, or titanium adhering to the wall of the processing chamber of the film forming apparatus can be removed (cleaned) or if deposit containing tantalum nitride, titanium nitride, tantalum, or titanium adheres to the supporting member of the semiconductor wafer of the susceptor and the like can be removed equally at a high etching rate without use of plasma, that is, without damaging to the processing chamber.

Particularly, by using process gas (for example, mixed gas of fluorine gas, nitric oxide gas and inert gas) containing fluorine gas with nitric oxide added, a deposit containing tantalum nitride, titanium nitride, tantalum, or titanium adhering to the wall of the processing chamber of the film forming apparatus can be removed at a higher etching rate. Further, a high etching rate of the deposit can be achieved on a low temperature side (for example, 200° C.) in the above-mentioned heating temperature range (100° C. to 500° C.).

Therefore, generation of particles originating from the deposit and adhering of the particles to the semiconductor wafer can be prevented when the thin film made of tantalum nitride, titanium nitride, tantalum, or titanium is formed on the semiconductor wafer within the processing chamber on a next stage. Consequently, a high quality thin film made of tantalum nitride, titanium nitride, tantalum, or titanium having an excellent film quality can be formed.

Further, a film forming apparatus capable of cleaning a deposit containing tantalum nitride, titanium nitride, tantalum, or titanium equally at a high etching rate can be achieved according to the embodiment.

Hereinafter, the embodiment of the present invention will be described about the sheet-feed type thermo CVD film forming apparatus of FIG. 1.

### Examples 1 to 6

A tantalum nitride thin film (TaN thin film) of 2000 Å in thickness was formed on an aluminum sheet surface so as to produce a sample. The sample was carried onto the susceptor 2 within the processing chamber 1 of the film forming apparatus shown in FIG. 1. Subsequently, fluorine gas (F₂) and nitrogen (N₂) gas were supplied into the processing chamber 1 from the process gas supply means 21, and cleaning was carried out under the following conditions.

Conditions of Examples 1 to 3
Gas mixture: 20% by volume of F₂—N₂
Flow rate of mixed gas: 1 slm
Pressure in processing chamber: 5 Torr (Example 1), 10 Torr (Example 2) and 40 Torr (Example 3)
Sample heating temperature: 200° C.

Conditions of Examples 4 to 6
Gas mixture: 20% by volume of F₂—N₂
Flow rate of mixed gas: 1 slm
Pressure in processing chamber: 5 Torr (Example 4), 10 Torr (Example 5) and 40 Torr (Example 6)
Sample heating temperature: 300° C.

Etching velocity of the TaN thin film at the time of cleaning was measured. To measure the etching velocity, cleaning was executed for a minute and then by breaking a sample, reduction of the film thickness of the TaN thin film during the cleaning was observed from sideway with an electronic microscope (S-900, manufactured by Hitachi, Ltd) under the condition of acceleration voltage of 10 kV, and its measurement value was converted to a value per minute. Table 1 shows the result.

TABLE 1

| | Heating | Pressure in | Etching rate |
|---|---|---|---|
| | temperature | chamber (Torr) | (Å/min) |
| Example 1 | 200 | 5 | 3 |
| Example 2 | | 10 | 12 |
| Example 3 | | 40 | 17 |
| Example 4 | 300 | 5 | 132 |
| Example 5 | | 10 | 220 |
| Example 6 | | 40 | 780 |

From Table 1, it is evident that when mixed gas of F₂ gas and N₂ gas is used as the process gas, the etching velocity of the TaN thin film as the sample can be increased on a higher pressure side under the condition that the pressure in the processing chamber is reduced, that is, on the side at which partial pressure of F₂ gas within the processing chamber is high. Particularly, it is evident that Examples 4 to 6 in which the heating temperature of the sample is set to 300° C. can raise the etching velocity of the TaN thin film about by one digit as compared to Examples 1 to 3 in which the heating temperature of the sample is set to 200° C.

### Examples 7 to 10

The etching velocity of the TaN thin film of the sample was measured according to the same method as Example 2 except that the same sample as Examples 1 to 6 was heated to temperatures of 100° C., 250° C., 350° C., and 500° C. Table 2 shows the result. In the meantime, Table 2 includes Example 2 and Example 5 of the Table 1.

TABLE 2

| | Heating | Etching rate |
|---|---|---|
| | temperature (° C.) | (Å/min) |
| Example 7 | 100 | 5 |
| Example 2 | 200 | 12 |
| Example 8 | 250 | 168 |
| Example 5 | 300 | 220 |
| Example 9 | 350 | 485 |
| Example 10 | 500 | 1200 |

From Table 2, it is evident that the etching velocity of the TaN thin film as the sample can be increased with increase of heating temperature in cleaning with mixed gas of F₂ gas and N₂ gas as the process gas.

### Examples 11 and 12

The same sample as Examples 1 to 6 was carried onto the susceptor 2 within the processing chamber 1 of the film forming apparatus shown in FIG. 1. Cleaning was executed under the following condition by supplying fluorine gas (F₂) gas, nitric oxide (NO) gas, and nitrogen gas (N₂) into the processing chamber 1 from the process gas supply means 21.

Conditions of Examples 11 and 12
Gas mixture: 2% by volume of NO-20% by volume of F₂—N₂
Flow rate of mixed gas: 1 slm
Pressure of processing chamber: 10 Torr
Sample heating temperature: 200° C. (Example 11), 500° C. (Example 12)

Etching velocity of the TaN thin film at the time of cleaning was measured. To measure the etching velocity, cleaning was executed for 30 seconds and then by breaking a sample, reduction of the film thickness of the TaN thin film during the cleaning was observed from sideway with an electronic microscope (S-900, manufactured by Hitachi, Ltd) under the condition of acceleration voltage of 10 kV, and its measurement value was converted to a value per minute. Table 3 shows the result. In the meantime, Table 3 contains Example 2 and Example 10 of Table 2.

TABLE 3

| | Heating | Composition of | Etching rate |
|---|---|---|---|
| | temperature (° C.) | process gas | (Å/min) |
| Example 2 | 200 | F₂ + N₂ | 12 |
| Example 11 | | F₂ + NO + N₂ | 200 |
| Example 10 | 500 | F₂ + N₂ | 1200 |
| Example 12 | | F₂ + NO + N₂ | 2700 |

From Table 3, it is evident that cleaning using mixed gas of NO gas, F₂ gas and N₂ gas as the process gas can intensify the etching velocity of TaN thin film of the sample by more than one digit at 200° C. and by more than twice at 500° C. as compared to cleaning using mixed gas of F₂ gas and N₂ gas as the process gas.

Cleaning of tantalum nitride thin film has been described in Examples 1 to 12. The cleaning could be executed under substantially the same condition as those in Examples 1 to 12 of the tantalum thin film (Ta thin film).

### Example 13-16

With similar methodology as described in Examples 1-12, etching velocity of a thin film made of TiN was examined. Table 4 shows the results of etching rate of cleaning mixtures made of fluorine (F₂), nitrogen (N₂), and nitric oxide (NO). Temperature and process gas composition were varied as shown to obtain the varied etching rates.

Cleaning of Titanium nitride thin film has been described in Examples 13 to 16. The cleaning could be executed under substantially the same condition as those in Examples 13 to 16 for the titanium thin film (Ti thin film).

TABLE 4

| | Heating | Composition of | Etching rate |
|---|---|---|---|
| | temperature (° C.) | process gas | (Å/min) |
| Example 13 | 400 | F₂ + N₂ | 800 |
| Example 14 | 250 | F₂ + 2% NO + N₂ | 5400 |
| Example 15 | 150 | F₂ + 2% NO + N₂ | 700 |
| Example 16 | | F₂ + 5% NO + N₂ | 2800 |

### BRIEF DESCRIPTION OF DRAWING

FIG. 1 is a schematic diagram showing a film forming apparatus equipped with a cleaning system according to one embodiment.

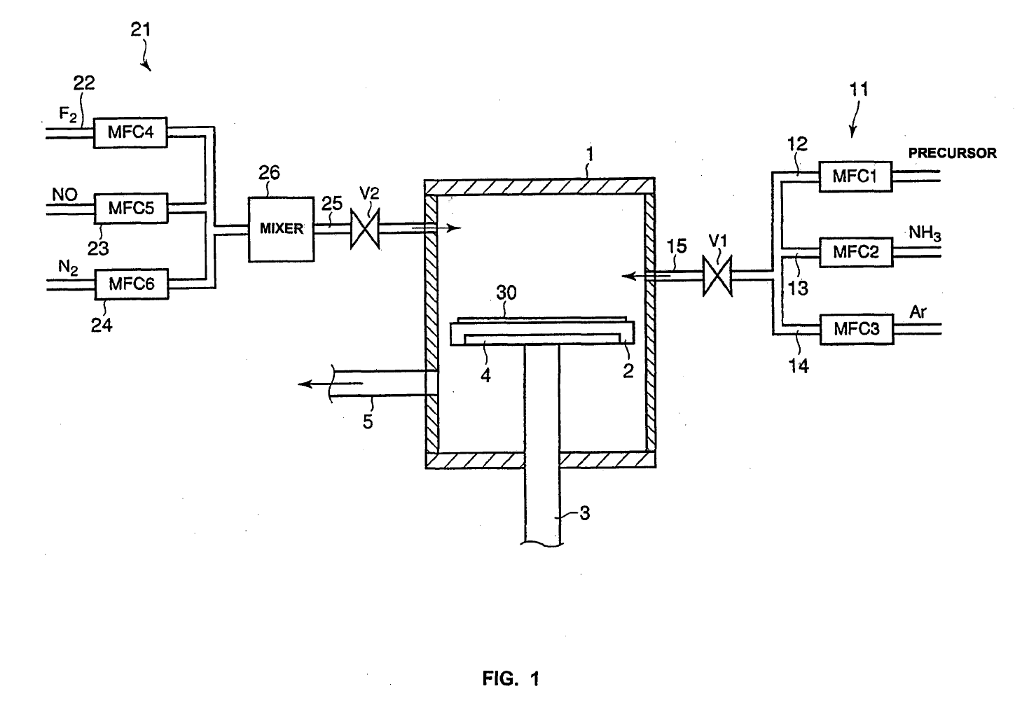

### EXPLANATION OF REFERENCE SYMBOLS

1: Processing chamber, 2: Susceptor, 4: Heater, 5: Exhaust pipe, 11: Raw material gas supply means, 12 to 14, 22 to 24: Supply pipe, MFC to MFC6: Mass flow controller, V1, V2: On-off valve, 21: Process gas supply means, 30: Semiconductor wafer

1-12. (canceled)

13. A method of cleaning a film forming apparatus for removing a deposit containing tantalum nitride, titanium nitride, tantalum, or titanium deposited on a processing chamber of the film forming apparatus after it is used for forming a thin film made of tantalum nitride, titanium nitride, tantalum, or titanium, the cleaning method comprising:
a step of supplying process gas containing fluorine gas into the processing chamber of the film forming apparatus; and
a step of heating the processing chamber.

14. The cleaning method of claim 13, wherein the process gas is mixed gas of the fluorine gas and inert gas.

15. The cleaning method of claim 13, wherein the process gas is mixed gas having a composition composed of 5 to 80% by volume of fluorine gas while the remainder is inert gas.

16. The cleaning method of claim 13, wherein the process gas further contains nitric oxide gas.

17. The cleaning method of claim 16, wherein the process gas with the nitric oxide gas added has a composition composed of 5 to 80% by volume of fluorine gas and 1 to 20% by volume of nitric oxide gas while the remainder is inert gas.

18. The cleaning method of claim 14, wherein the inert gas is at least one gas selected from nitrogen and rare gas.

19. The cleaning method of claim 17, wherein the inert gas is at least one gas selected from nitrogen and rare gas.

20. The cleaning method of claim 13, wherein the process gas is depressurized and heated within the processing chamber.

21. The cleaning method of claim 20, wherein the degree of depressurization in the processing chamber is 0.1 to 700 Torr.

22. The cleaning method of claim 13, wherein the heating temperature of the processing chamber is 100° C. to 500° C.

23. A film forming apparatus which forms a thin film made of tantalum nitride, titanium nitride, tantalum, or titanium on a wafer within a processing chamber, comprising:
raw material supply means for supplying raw material gas for forming a thin film made of tantalum nitride, titanium nitride, tantalum, or titanium in the processing chamber;
process gas supply means for supplying process gas containing fluorine gas into the processing chamber; and
heating means for heating the processing chamber.

24. The film forming apparatus of claim 23, wherein the process gas supply means supplies process gas containing fluorine gas with nitric oxide added within the processing chamber.

25. The film forming apparatus of claim 23, further comprising exhaust means for depressurizing the inside of the processing chamber.
